(19) United States
(12) Patent Application Publication
(10) Pub. No.: US 2024/0113495 A1
(43) Pub. Date: Apr. 4, 2024

(54) LASER MODULE

(71) Applicant: Panasonic Intellectual Property Management Co., Ltd., Osaka (JP)

(72) Inventor: MITSUOKI HISHIDA, Gifu (JP)

(21) Appl. No.: 18/537,885

(22) Filed: Dec. 13, 2023

Related U.S. Application Data
(63) Continuation of application No. PCT/JP2022/025525, filed on Jun. 27, 2022.

(30) Foreign Application Priority Data
Jul. 27, 2021 (JP) 2021-122249

(51) Int. Cl. H01S 5/02208

(52) U.S. Cl. CPC H01S 5/02208

(57) ABSTRACT

A plurality of recesses (15) is formed in a surface of first block (10), the surface facing second block (20). The plurality of recesses (15) are formed in a region different from a region in which laser element (40) is disposed when viewed from a direction in which first block (10) and second block (20) are stacked. Each of recesses (15) is provided with a spacer member (50) having insulation properties. Spacer member (50) partly protrudes from corresponding recess (15). Spacer member (50) is sandwiched between first block (10) and second block (20).

### TECHNICAL FIELD

The present disclosure relates to a laser module.

### BACKGROUND ART

PTL 1 discloses a semiconductor laser device including a heat sink, a sub-mount, a first block (first electrode), an insulation layer, a semiconductor laser element, a connection portion, and a second block (second electrode).

The semiconductor laser element includes a light emitting surface that outputs a laser beam when a current flows from a positive electrode toward a negative electrode. The semiconductor laser element generates heat that is dissipated from the first block and the second block to the heat sink.

### CITATION LIST

### Patent Literature

PTL 1: WO 2017/183300 A

### SUMMARY OF THE INVENTION

### Technical Problem

The invention of PTL 1 causes the first block and the second block to be insulated from each other by interposing an insulation layer in a sheet-like shape between the first block and the second block. Here, enhancing thermal conductivity between the first block and the second block requires a gap between the first block and the second block to be further reduced.

The present disclosure has been made in view of such a point, and an object of the present disclosure is to ensure insulation properties while a gap between the first block and the second block is reduced.

### Solutions to Problem

A first aspect of the present invention is a laser module including: a laser element that emits a laser beam; a first block electrically connected to a first electrode of the laser element; and a second block disposed opposite to the first block and electrically connected to a second electrode of the laser element. The first block includes a first surface facing the second block and the second block includes a second surface facing the first block. Any one of the first surface and the second surface includes a plurality of recesses formed in a region different from a region in which the laser element is disposed when viewed from a direction in which the first block and the second block are stacked. Each of the recesses is provided with a spacer member having insulation properties and the spacer member partly protrudes from the corresponding recess. The spacer member is sandwiched between the first block and the second block.

In the first aspect of the present invention, the plurality of recesses are formed in the first surface of the first block, the first surface facing the second block, or are formed in the second surface of the second block, the second surface facing the first block. The plurality of recesses is formed in the region different from the region in which the laser element is disposed when viewed from a direction in which the first block and the second block are stacked. Each of the recess is provided with the spacer member having insulation properties. The spacer member partly protrudes from the corresponding recess. The spacer member is sandwiched between the first block and the second block.

This configuration enables setting a gap between the first block and the second block based on an amount of protrusion of each of the spacer members from the corresponding recesses. This configuration enables insulation properties to be ensured while reducing the gap between the first block and the second block.

In a second aspect of the present invention, the laser module of the first aspect of the present invention includes an insulation layer provided by applying an insulation paste material between the first block and the second block.

In the second aspect of the present invention, heat conduction is facilitated between the first block and the second block by applying an insulation paste material between the first block and the second block to provide the insulation layer. Additionally, the gap between the first block and the second block is defined by the spacer members, so that the paste material is prevented from having an uneven thickness.

In a third aspect of the present invention, the laser module according to the first or second aspect of the present invention includes the laser element that is disposed on a virtual straight line connecting two of the plurality of recesses when viewed from the direction in which the first block and the second block are stacked.

In the third aspect of the present invention, the gap between the first block and the second block can be accurately managed at a position near the laser element by disposing the laser element on the virtual straight line connecting the two recesses.

In a fourth aspect of the present invention, the laser module according to any one of the first to third aspects of the present invention includes the spacer member that is formed in a spherical shape.

In the fourth aspect of the present invention, the spacer member is formed in a spherical shape so that there is no need to consider an orientation and posture of the spacer member when the spacer member is fitted into the corresponding recess. This enables improving ease of assembly of the laser module.

In a fifth aspect of the present invention, the laser module according to any one of the first to fourth aspects of the present invention includes at least three of the spacer members.

In the fifth aspect of the present invention, at least three of the spacer members are provided so that the second block can be supported at three points with respect to the first block. This enables the gap to be managed more accurately.

### Advantageous Effect of Invention

The present disclosure enables insulation properties to be ensured while reducing the gap between the first block and the second block.

### BRIEF DESCRIPTION OF THE DRAWINGS

FIG. 1 is a perspective view illustrating a configuration of a laser module according to an exemplary embodiment.

FIG. 2 is an exploded perspective view illustrating a configuration of a laser module.

FIG. 3 is a plan view illustrating a configuration of a laser module.

FIG. 4 is a front sectional view illustrating a configuration of a laser module for illustrating a fastening structure of a first block and a second block.

FIG. 5 is a front sectional view illustrating a configuration of a laser module for illustrating placement of spacer members.

### DESCRIPTION OF EMBODIMENT

Exemplary embodiments of the present invention are described below with reference to the drawings. The description below of preferred exemplary embodiments is merely exemplary in nature, and is not intended to limit the present disclosure, its application, or its use.

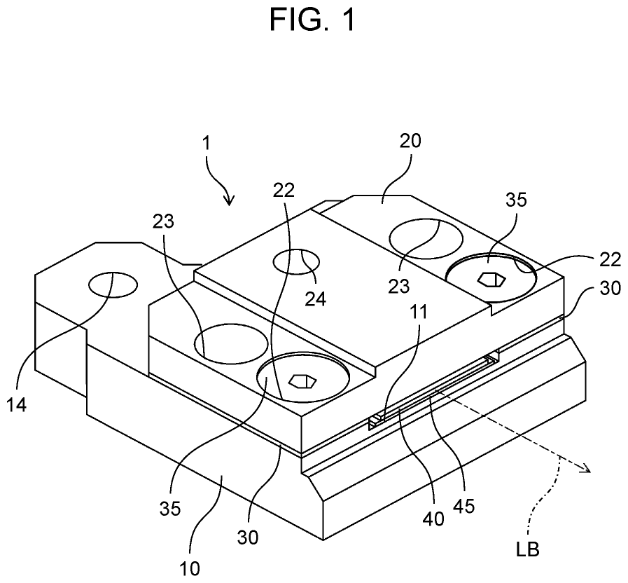

As illustrated in FIGS. 1 to 4, laser module 1 includes first block 10, second block 20, insulation layer 30, laser element 40, sub-mount 45, and spacer member 50.

First block 10 is conductive. First block 10 is mainly made of copper (Cu). First block 10 made of copper is plated with nickel (Ni) and gold (Au), sequentially. First block 10 is connected to a water-cooling jacket (not illustrated).

First block 10 includes an upper surface provided with mount portion 11. Mount portion 11 is formed by recessing a part of the upper surface of first block 10. Mount portion 11 is provided in an end portion of the upper surface in a direction in which laser beam LB is emitted (an emission direction indicated by an arrow in FIG. 1). Laser element 40 and sub-mount 45 are disposed on mount portion 11. Laser beam LB is emitted from laser element 40 in the emission direction.

First block 10 is provided with first screw hole 12, second screw hole 13, first terminal hole 14, and recess 15. Two first screw holes 12 are provided at an interval in a direction orthogonal to the emission direction of laser beam LB. Mount portion 11 is provided between two first screw holes 12.

Two second screw holes 13 are provided at an interval in a direction orthogonal to emission direction 5 of laser beam LB. Second screw hole 13 is provided away from first screw hole 12 in a direction opposite the emission direction of laser beam LB.

First terminal hole 14 is provided in an end portion in first block 10 in the direction opposite the emission direction of laser beam LB. That is, first terminal hole 14 is provided in the end portion of first block 10, the end portion being opposite mount portion 11. The first terminal hole 14 is formed of a screw hole. First terminal hole 14 is connected to a connection terminal for a power supply.

As will be described in detail later, three recesses 15 are provided. Recesses 15 are provided with respective spacer members 50 having insulation properties.

Insulation layer 30 has insulation properties. Insulation layer 30 is made of a paste material that is applied between first block 10 and second block 20 and then solidified. After spacer members 50 are disposed, insulation layer 30 is disposed surrounding mount portion 11 on the upper surface of first block 10.

Laser element 40 includes a lower surface serving as positive electrode 40a (first electrode), and an upper surface serving as negative electrode 40b (second electrode). Laser element 40 includes a light emitting surface that outputs laser beam LB when a current flows from positive electrode 40a toward negative electrode 40b.

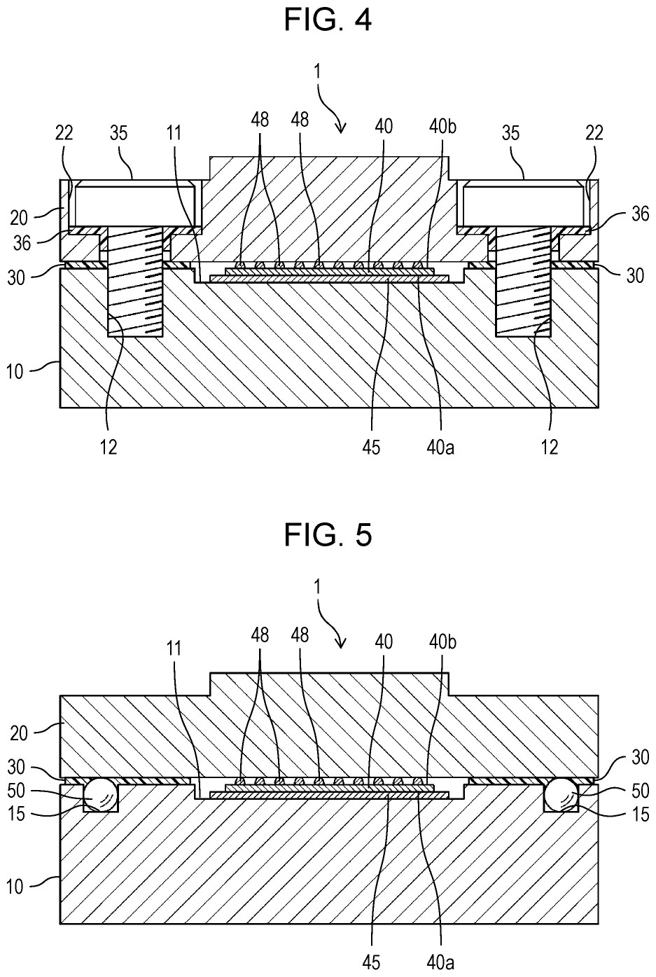

Laser element 40 is placed on sub-mount 45. Positive electrode 40a of laser element 40 of laser element 40 is electrically connected to sub-mount 45. Laser element 40 and sub-mount 45 are disposed on mount portion 11. First block 10 functions as an electrode block electrically connected to positive electrode 40a of laser element 40 with sub-mount 45. Negative electrode 40b of laser element 40 includes bump 48 (see FIG. 4).

Bump 48 is conductive. Bump 48 is mainly made of gold (Au). A plurality of bumps 48 is provided on negative electrode 40b of laser element 40.

Bump 48 is bonded to negative electrode 40b by bringing a gold wire having a spherical tip due to melting into contact with negative electrode 40b and applying an ultrasonic wave to the gold wire. Bump 48 is electrically connected to negative electrode 40b of laser element 40.

Second block 20 is conductive. Second block 20 is mainly made of copper (Cu). Second block 20 includes a block made of copper that is plated with nickel (Ni) and gold (Au), sequentially. Second block 20 is disposed facing first block 10.

Second block 20 is provided on laser element 40 and insulation layer 30. Second block 20 is electrically connected to laser element 40 with the bump 48. Second block 20 functions as an electrode block electrically connected to negative electrode 40b of laser element 40.

Second block 20 is in close contact with insulation layer 30 in a region other than a region facing laser element 40 on a lower surface of second block 20.

Second block 20 includes first through-hole 22, second through-hole 23, and second terminal hole 24. First through-hole 22 is provided at a position corresponding to first screw hole 12 of first block 10. First through-hole 22 is formed as a counterbore hole that allows ingress of a head of conductive screw 35 for fastening first block 10 and second block 20.

Second through-hole 23 is provided at a position corresponding to second screw hole 13 of first block 10.

Second terminal hole 24 is provided in a central portion of second block 20. Second terminal hole 24 is connected to a connection terminal for a power supply.

Mount portion 11 has a depth (height) that is set in consideration of a thickness of each of laser element 40, sub-mount 45, bump 48, and insulation layer 30.

First block 10 and second block 20 are fastened to each other by conductive screw 35. Conductive screw 35 is inserted into first through-hole 22 of second block 20 and first screw hole 12 of first block 10.

Between conductive screw 35 and second block 20, insulation member 36 is provided (see FIG. 4). This configuration enables first block 10 and second block 20 to be fastened to each other while electrically insulating first block 10 from second block 20.

First block 10 and second block 20 are fastened by an insulation screw (not illustrated) while being electrically insulated from each other. The insulation screw is inserted into second through-hole 23 of second block 20 and second screw hole 13 of first block 10.

Instead of the insulation screw, conductive screw 35 and insulation member 36 may be used. Alternatively, an insulation screw may be used instead of conductive screw 35 and insulation member 36.

Laser module 1 configured as described above includes laser element 40 with a side surface serving as the light emitting surface that outputs laser beam LB when a current flows from positive electrode 40a toward negative electrode 40b of laser element 40. At this time, laser element 40 generates heat that is transferred to first block 10 and second block 20, and is dissipated.

<Gap Management of First Block and Second Block>

When laser element 40 is heated to high temperature, laser element 40 may deteriorate in performance such as a decrease in laser output. Thus, there is a demand for more stabilizing the performance of laser element 40 by efficiently transferring and dissipating the heat generated in laser element 40.

To enhance thermal conductivity between first block 10 and second block 20, laser module 1 of the present exemplary embodiment has a structure in which insulation properties can be secured while a gap between first block 10 and second block 20 is reduced.

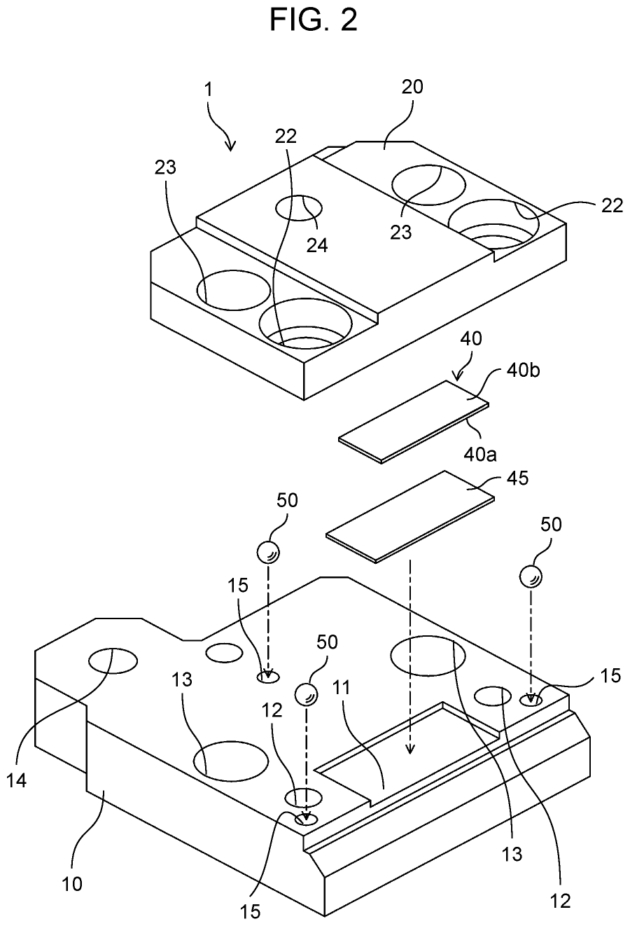

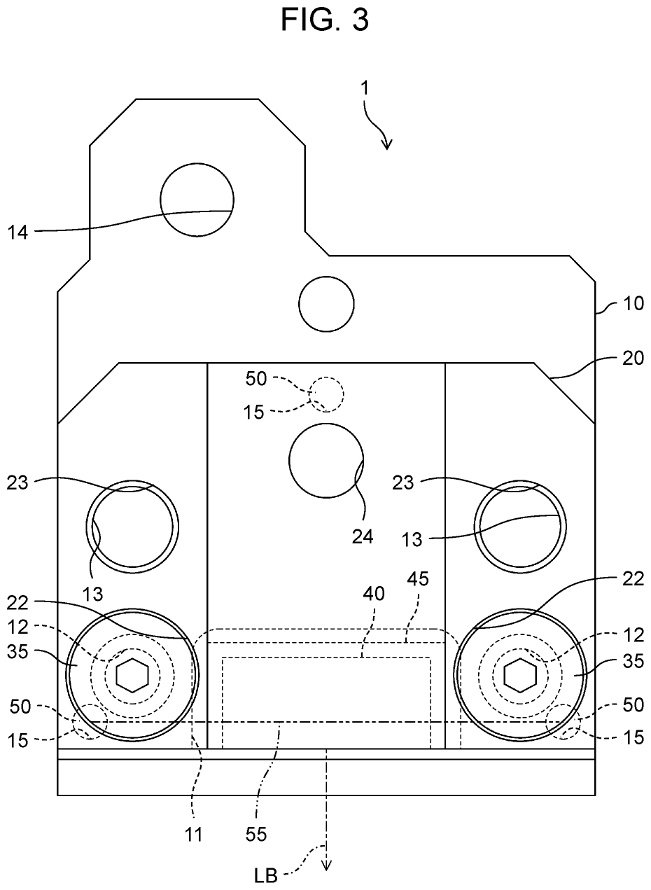

Specifically, a plurality of recesses 15 is formed on a surface (upper surface in FIG. 2) of first block 10, the surface facing second block 20, as illustrated in FIGS. 2 and 3. The plurality of recesses 15 is formed in the region different from the region in which laser element 40 is disposed when viewed from a direction in which first block 10 and second block 20 are stacked.

FIG. 3 illustrates an example in which three recesses 15 are provided. Two of three recesses 15 are provided outside two first screw holes 12 in a width direction and are provided on a side where laser beam LB is emitted. As a result, laser element 40 is disposed on virtual straight line 55 connecting two recesses 15 when viewed from the direction in which first block 10 and second block 20 are stacked.

One remaining recess 15 is provided away from second screw hole 13 in the direction opposite to the emission direction of laser beam LB and is provided at a center position in the width direction of first block 10. As described above, three recesses 15 are provided at respective apexes of an isosceles triangle. Spacer member 50 is disposed in recess 15.

Spacer member 50 is composed of a member having insulation properties. Spacer member 50 is made of alumina (Al₂O₃), for example. The spacer member 50 is formed in a spherical shape. As described above, ease of assembly of laser module 1 is improved due to spacer member 50 that is formed in a spherical shape that is not required to consider an orientation and an attitude of spacer member 50 when spacer member 50 is fitted into recess 15.

Although FIG. 2 illustrates an example in which recess 15 is formed in the upper surface of first block 10, and spacer member 50 is disposed in recess 15 of first block 10, the present invention is not limited to this configuration. For example, recess 15 may be formed on the lower surface of second block 20, and spacer member 50 may be disposed in recess 15 of second block 20.

As illustrated in FIG. 5, spacer member 50 partly protrudes from recess 15. Spacer member 50 is sandwiched between first block 10 and second block 20. This configuration enables setting a gap between first block 10 and second block 20 based on an amount of protrusion of spacer member 50 from recess 15. This configuration also prevents a paste material applied to form insulation layer 30 from having an uneven thickness, and enables ensuring insulation properties while reducing a gap between first block 10 and second block 20 to improve thermal conductivity.

The present exemplary embodiment enables the gap between first block 10 and second block 20 to be accurately managed at a position near laser element 40 by disposing laser element 40 on virtual straight line 55 connecting two recesses 15.

The gap can be managed more accurately by providing three recesses 15 at respective apexes of an isosceles triangle and disposing spacer member 50 in each of recesses 15 to enable second block 20 to be supported at three points with respect to first block 10.

### Other Exemplary Embodiments

The exemplary embodiment may have the following configuration.

Although the configuration is described in the present exemplary embodiment in which second block 20 is supported at three points by providing three spacer members 50, the present invention is not limited to this configuration. For example, second block 20 may be supported at four or more points by providing four or more spacer members 50.

The present exemplary embodiment allows alumina (Al₂O₃), silicon nitride (Si₃N₄), silicon carbide (SiC), boron nitride (BN), aluminum nitride (AlN), zirconia (ZrO₂), or the like to be used, as a material of spacer member 50.

As the material of spacer member 50, Teflon (registered trademark), polyether ether ketone (PEEK), glass, or the like can also be used.

As a material of the paste material constituting insulation layer 30, an adhesive resin can be used. For example, an acrylic resin, a silicone resin, a thermoplastic resin, a thermosetting resin, or the like can be used.

As the material of the paste material, a containing filler can also be used. For example, a filler containing any of alumina (Al₂O₃), boron nitride (BN), aluminum nitride (AlN), zirconia (ZrO₂), silicon nitride (Si₃N₄), silicon carbide (SiC), zinc nitride (Zn₃N₂), cermet (TiC, TiN), yttria (Y₂O₃), zirconia (ZrO₂), and magnesium oxide (MgO) can be used.

### INDUSTRIAL APPLICABILITY

As described above, the present disclosure is extremely useful and has high industrial applicability because a highly practical effect can be obtained in which insulation properties can be secured while a gap between the first block and the second block is reduced.

### REFERENCE MARKS IN THE DRAWINGS

1 laser module
10 first block
15 recess
20 second block
30 insulation layer
40 laser element
40a positive electrode (first electrode)
40b negative electrode (second electrode)
50 spacer member
55 virtual straight line
LB laser beam

1. A laser module comprising:
a laser element that emits a laser beam;
a first block electrically connected to a first electrode of the laser element; and
a second block disposed opposite to the first block and electrically connected to a second electrode of the laser element,
wherein
the first block includes a first surface facing the second block and the second block includes a second surface facing the first block,
any one of the first surface and the second surface includes a plurality of recesses formed in a region different from a region in which the laser element is disposed when viewed from a direction in which the first block and the second block are stacked,
each of the plurality of recesses is provided with a spacer member having insulation properties,
the spacer member partly protrudes from the corresponding recesses, and
the spacer member is sandwiched between the first block and the second block.

2. The laser module according to claim 1, further comprising an insulation layer provided by applying an insulation paste material between the first block and the second block.

3. The laser module according to claim 1, wherein the laser element is disposed on a virtual straight line connecting two of the plurality of recesses when viewed from the direction in which the first block and the second block are stacked.

4. The laser module according to claim 1, wherein the spacer member is formed in a spherical shape.

5. The laser module according to claim 1, wherein at least three of the spacer members are provided.
